(19) United States
(12) Patent Application Publication
(10) Pub. No.: US 2023/0408919 A1
(43) Pub. Date: Dec. 21, 2023

(54) MANUFACTURING MIXED WETTABILITY SURFACES

(71) Applicants: Saudi Arabian Oil Company, Dhahran (SA); King Abdullah University of Science and Technology, Thuwal-Jeddah (SA)

(72) Inventors: Dong Kyu Cha, Dhahran (SA); Abdullah Abdulaziz AlOmier, Thuwal (SA); Subhash C. Ayirala, Dhahran (SA); Mohammed Badri Al-Otaibi, Dhahran (SA); Ali Abdallah Al-Yousef, Dhahran (SA); Hussein Hoteit, Thuwal (SA)

(73) Assignees: Saudi Arabian Oil Company, Dhahran (SA); King Abdullah University of Science and Technology, Thuwal-Jeddah (SA)

(21) Appl. No.: 18/335,603

(22) Filed: Jun. 15, 2023

Related U.S. Application Data
(60) Provisional application No. 63/353,267, filed on Jun. 17, 2022.

(51) Int. Cl. G03F 7/039; G03F 7/20; G03F 7/038; G03F 7/16; G03F 7/075; G03F 7/38; G09B 23/40

(52) U.S. Cl. CPC G03F 7/039; G03F 7/2004; G03F 7/038; G09B 23/40; G03F 7/0752; G03F 7/38; G03F 7/162

(57) ABSTRACT

A method for manufacturing a micromodel with a mixed wettability surface representing a hydrocarbon reservoir is disclosed. The method includes coating a top surface of a hydrophilic substrate with photoresist, covering a top of the photoresist with a photomask, exposing the covered top of the photoresist to UV light that changes a chemical property of a region of the photoresist corresponding to a pattern of the photomask, removing the photomask, removing the region of the photoresist corresponding to the pattern of the photomask based on the chemical property of the region, depositing a hydrophobic thin-film on top of the hydrophilic substrate, and removing a remaining photoresist covered with the thin-film, such that the surface of the hydrophilic substrate is patterned with both a region covered with the hydrophobic thin-film and an uncovered region of the hydrophilic substrate, creating a mixed wettability surface on the hydrophilic substrate that represents the micromodel.

### BACKGROUND

A multiphase fluid flow is the commingled flow of fluids with different phases. Thus, a fluid including water, oil, and gas is a fluid with different phases. Fundamental understanding of complex fluid transport and multiphase flow in porous media is crucial for many industrial processes, including engineering applications across different disciplines, such as biomedical, environmental, and petroleum engineering.

Micromodels are an emerging platform to represent porous media with sophisticated structural shapes and pore sizes. Paper models gained wide industrial attention for massive scalability and capabilities for pore-scale observation of fundamental mechanisms for fluid recovery and mimicking the actual rock pore-network at high spatial resolution.

Imbibition is the process of absorbing a wetting phase into a porous rock. Wettability is the preference of a solid to contact one liquid or gas, known as the wetting phase, rather than another liquid or gas. The wetting phase tends to spread on the surface of the solid and a porous solid tends to imbibe the wetting phase. The wettability of a rock is determined by which phase imbibes more. The nonwetting phase is displaced by the wetting phase. Rocks may be water-wet, oil-wet, or intermediate-wet. Rock mixed wettability is a type of surface wettability in which the surface of a rock exhibits both water-wet and oil-wet characteristics. This can occur due to a number of factors, including the chemical composition of the rock, the presence of natural organic compounds, and the interaction of fluids with the rock surface.

Drainage is the process of forcing a nonwetting phase, such as oil, into a porous rock. In the presence of solid surfaces, the fluid-fluid displacement is affected by wettability of porous media and solid surfaces, drainage or imbibition, and multiphase flow. Displacement efficiency is the fraction of oil recovered from a zone swept by a displacement fluid, such as water.

While recent advances focus on coating of the micromodels, current technologies are capable of building micromodels that are either water-wet or oil-wet. Surface treatments to alter surface wettability use different materials and techniques. However, a method to achieve a representative mixed-wet conditions, where selective hydrophilic and hydrophobic zones are precisely controlled, is still missing in the existing knowledge.

Accordingly, there exists a need for a method for manufacturing a micromodel with mixed wettability surfaces representing a hydrocarbon reservoir.

### SUMMARY

In general, in one aspect, the invention relates to a method for manufacturing a micromodel with a mixed wettability surface representing a hydrocarbon reservoir. The method includes coating a top surface of a hydrophilic substrate with photoresist, covering a top of the photoresist with a photomask, wherein the photomask comprises a pattern transparent to UV light, exposing the covered top of the photoresist to UV light that changes a chemical property of a region of the photoresist corresponding to the pattern of the photomask, removing the photomask, removing the region of the photoresist corresponding to the pattern of the photomask based on the chemical property of the region, depositing a hydrophobic thin-film on top of the hydrophilic substrate, and removing a remaining photoresist covered with the thin-film, such that the surface of the hydrophilic substrate is patterned with both a region covered with the hydrophobic thin-film and an uncovered region of the hydrophilic substrate, creating a mixed wettability surface on the hydrophilic substrate that represents the micromodel.

In general, in one aspect, the invention relates to a method for manufacturing a micromodel with a mixed wettability surface representing a hydrocarbon reservoir. The method includes coating a top surface of a hydrophobic substrate with photoresist, covering a top of the photoresist with a photomask, wherein the photomask comprises a pattern transparent to UV light, exposing the covered top of the photoresist to UV light that changes a chemical property of a region of the photoresist corresponding to the pattern of the photomask, removing the photomask, removing the region of the photoresist based on the chemical property of the region, wherein the removed region corresponds to the pattern of the photomask, depositing a hydrophilic thin-film on top of the substrate, and removing a remaining photoresist covered with the hydrophilic thin-film, such that the surface of the hydrophobic substrate is patterned with both a region covered with the hydrophilic thin-film and an uncovered region of the hydrophobic substrate, creating a mixed wettability surface on the hydrophobic substrate that represents the micromodel.

In general, in one aspect, the invention relates to a method for manufacturing a micromodel with a mixed wettability surface representing a hydrocarbon reservoir. The method includes depositing a hydrophobic thin-film on a top surface of a hydrophilic substrate, coating a top of the hydrophobic thin-film with photoresist, covering a top of the photoresist with a photomask, wherein the photomask comprises a pattern transparent to UV light, exposing the covered top of the photoresist to UV light that changes a chemical property of a region of the photoresist corresponding to the pattern of the photomask, removing the photomask, removing a region of the photoresist based on the chemical property of the region, wherein the removed region corresponds to the pattern of the photomask, removing the hydrophobic thin-film in the region not covered by photoresist, and removing remaining photoresist, such that the surface of the substrate is patterned with both the region covered with the hydrophobic thin-film and an uncovered region of the hydrophilic substrate, creating a mixed wettability surface on the substrate that represents the micromodel.

In general, in one aspect, the invention relates to a method for manufacturing a micromodel with a mixed wettability surface representing a hydrocarbon reservoir. The method includes depositing a hydrophilic thin-film on a top surface of a hydrophobic substrate, coating a top of the thin-film with photoresist, covering a top of the photoresist with a photomask, wherein the photomask comprises a pattern transparent to UV light, exposing the covered top of the photoresist to UV light that changes a chemical property of a region of the photoresist corresponding to the pattern of the photomask, removing the photomask, removing a region of the photoresist based on the chemical property of the region, wherein the removed region corresponds to the pattern of the photomask, removing the thin-film in the region not covered by photoresist, and removing remaining photoresist, such that the surface of the substrate is patterned with both a region covered with the hydrophilic thin-film and an uncovered region of the hydrophobic substrate, creating a mixed wettability surface on the substrate that represents the micromodel.

Other aspects and advantages of the invention will be apparent from the following description and the appended claims.

### BRIEF DESCRIPTION OF DRAWINGS

FIG. 1 shows a flowchart of a first method for manufacturing a micromodel with a mixed wettability surface representing a hydrocarbon reservoir, according to one or more embodiments.

FIG. 2 shows a substrate undergoing the first method, according to one or more embodiments.

FIG. 3 shows a flowchart of a second method for manufacturing a micromodel with a mixed wettability surface representing a hydrocarbon reservoir, according to one or more embodiments.

FIG. 4 shows a substrate undergoing the second method, according to one or more embodiments.

FIG. 5 shows a schematic view of a substrate with a mixed wettability surface, according to one or more embodiments.

FIG. 6 shows a water droplet on the surface of the substrate, according to one or more embodiments.

FIG. 7 shows the substrate of FIG. 5 with a mixed wettability surface, according to one or more embodiments.

FIG. 8A shows a silicon-based substrate with a selective mixed wettability surface, according to one or more embodiments.

FIG. 8B shows mixed wettability surfaces, according to one or more embodiments.

### DETAILED DESCRIPTION

In the following detailed description of embodiments of the disclosure, numerous specific details are set forth in order to provide a more thorough understanding of the disclosure. However, it will be apparent to one of ordinary skills in the art that the disclosure may be practiced without these specific details. In other instances, well-known features have not been described in detail to avoid unnecessarily complicating the description.

Throughout the application, ordinal numbers (e.g., first, second, third, etc.) may be used as an adjective for an element (i.e., any noun in the application). The use of ordinal numbers is not to imply or create any particular ordering of the elements nor to limit any element to being only a single element unless expressly disclosed, such as using the terms “before”, “after”, “single”, and other such terminology. Rather, the use of ordinal numbers is to distinguish between the elements. By way of an example, a first element is distinct from a second element, and the first element may encompass more than one element and succeed (or precede) the second element in an ordering of elements.

In one aspect, embodiments disclosed herein relate to a method for manufacturing a micromodel with a mixed wettability surface representing a hydrocarbon reservoir, comprising the steps: coating a top surface of a hydrophilic substrate with photoresist, covering a top of the photoresist with a photomask, wherein the photomask comprises a pattern transparent to UV light, exposing the covered top of the photoresist to UV light that changes a chemical property of a region of the photoresist corresponding to the pattern of the photomask, removing the photomask, removing a region of the photoresist based on the chemical property of the region, wherein the removed region corresponds to the pattern of the photomask, depositing a hydrophobic thin-film on top of the substrate, and removing remaining photoresist covered with the thin-film, such that the surface of the substrate is patterned with a region covered with the hydrophobic thin-film, and an uncovered region of the hydrophilic substrate, creating a mixed wettability surface on the substrate that represents the micromodel.

The method for manufacturing a micromodel with a mixed wettability surface enables the creation of selective hydrophilic and hydrophobic regions that are precisely allocated on the surface of the substrate. Manufacturing micromodels with a selective wettability surface helps mimicking an actual mixed-wet rock that represents an oil or gas reservoir.

A silicon-based surface of the micromodel is in favorable compatibility for oil and gas applications, including high temperature and pressure and the affinity for crude oils and organic usage of solvents. The regions of the micromodel substrate coated with perfluorodecyltrichlorosilane (FDTS) shift the localized wetting state of the silicon towards hydrophobic, while the wettability of un-coated silicon substrate remains unchanged. The proposed manufacturing method results in a microfluidic device, also referred to as a “Reservoir-on-a-Chip”, with controlled mixed-wet properties.

Embodiments of the present disclosure may provide at least one of the following advantages. The method enables the creation of a hydrophobic surface in selected regions by altering the hydrophilic surface property of a substrate and vice versa. In this way, selective hydrophilic and hydrophobic zones can be incorporated and controlled precisely at micro- and nano-scales. Tuning the wetting state of the substrate to mimic any desired mixed-wet characteristics of a system, results in a pore-scale platform which enables tremendous opportunities for fundamental fluid flow analysis and fluid-surface interaction studies. Also, the method is able to be integrated and implemented in many fields of applications such as but not limited to microfluidics and electronics. Both the first and second method for manufacturing mixed wettability surfaces are applicable to un-patterned and patterned surfaces.

The method includes two main steps: photolithography, and thin-film deposition. Photolithography is the process of creating a geometric pattern from a photomask to a photoresist on the surface of the substrate. While thin-film deposition places a very thin layer of a material on the surface of the substrate. This step determines exactly the target wettability of the surface. Depending on the wettability state of the original surface of the substrate, deposition of either hydrophobic or hydrophilic material is performed in order to create the contrast in wettability.

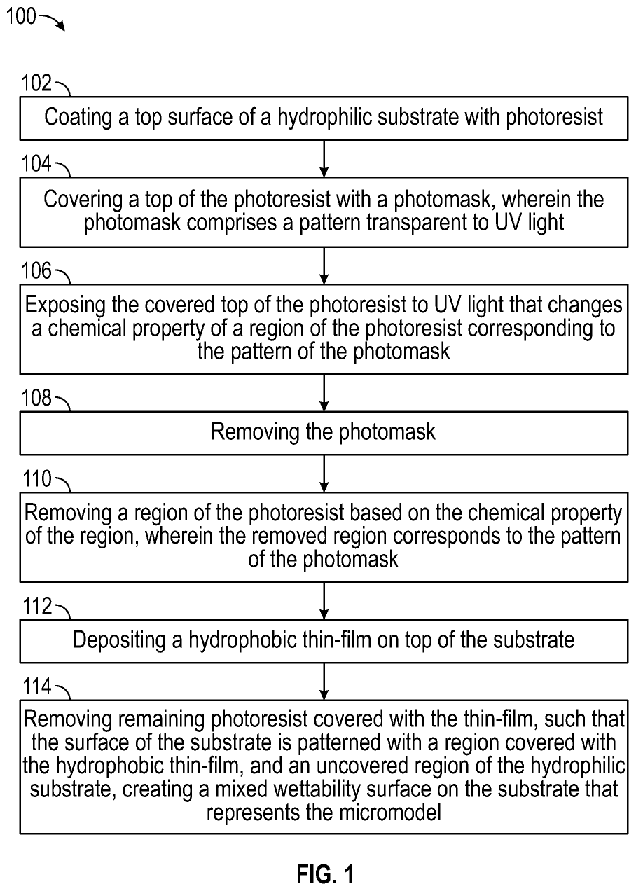

FIG. 1 shows a flowchart (100) of the method steps for manufacturing a mixed wettability surface, according to the first method of photolithography. The method includes the following steps.

In step 102, a top surface of a hydrophilic substrate is coated with photoresist. In some embodiments, the substrate is coated with photoresist by spin coating.

Spin coating is performed by a spin coater, or simply spinner. Spin coating deposits a uniform thin film onto the flat substrate. A relatively small amount of fluid photoresist is applied on the center of the substrate, while the substrate is either spinning at a low speed or not spinning at all. Then, the substrate rotates at a speed up to 10.000 rpm to spread the fluid photoresist by the centrifugal force. The substrate is rotated while the fluid photoresist spins off the edges of the substrate, until the desired thickness of the photoresist is achieved. The thickness of the photoresist depends on the viscosity of the photoresist and the spinning speed. The faster the spinning, the thinner the photoresist. Then, the fluid photoresist is dried.

In step 104, a top of the photoresist is covered with a photomask, wherein the photomask includes a pattern transparent to UV light. The pattern of the photomask includes holes or transparencies in the photomask that allow UV light to shine through the photomask. The resolution of the pattern may be as fine as 1 μm. The pattern may include squares, circles, triangles, or any other geometrical shape.

There are two types of photoresist: Positive and negative photoresist. In case of a positive photoresist, the region exposed to UV light is degraded by the UV light. The region covered by the photomask from UV light remains undegraded. In case of a negative photoresist, the region of the photoresist exposed to UV light is strengthened and the region covered by the photomask from UV light remains weak. Both the first and second method are applicable to positive and negative photoresist.

In step 106, the covered top of the photoresist is exposed to UV light that changes a chemical property of a region of the photoresist corresponding to the pattern of the photomask. In some embodiments, the UV light has a wavelength between 10 nm to 400 nm.

In step 108, the photomask is removed. The photomask may be removed separately from or together with the photoresist as described in the next step.

In step 110, a region of the photoresist is removed based on the chemical property of the region, wherein the removed region corresponds to the pattern of the photomask. In some embodiments, the chemical property includes degradation, or hardness. The removed region of the photoresist also corresponds to the pattern of the region exposed to UV light. The type of the photoresist determines if the region of the photoresist exposed to UV light or the region of the photoresist not exposed to UV light are removed.

The region of the photoresist is removed by photoresist developer. In case of a positive photoresist, the region of the photoresist degraded by the UV light becomes soluble to the photoresist developer and the undegraded region of the photoresist remains insoluble to the photoresist developer. In case of a negative photoresist, the region of the photoresist strengthened by the UV light becomes insoluble to the photoresist developer and the weak region of the photoresist is dissolved by the photoresist developer.

In step 112, a hydrophobic thin-film is deposited on top of the substrate. The thin-film may be deposited by atomic layer deposition (ALD), molecular layer deposition (MVD), pulsed laser deposition (PLD), physical vapor deposition (PVD), chemical vapor deposition (CVD), sputtering, or evaporation. ALD is a thin-film deposition technique based on the sequential use of a gas-phase chemical process. ALD uses two chemicals called precursors, that react with the surface of the substrate one at a time. A thin film is slowly deposited through repeated exposure to separate precursors. MVD is the gas-phase reaction between surface reactive chemicals and an appropriately receptive surface of the substrate. The thin-film is deposited on the surface of the substrate to obtain the desired wetting properties. PLD focuses a high-power pulsed laser beam inside a vacuum chamber to strike a target of the thin-film material. The thin-film material is vaporized from the target in a plasma plume and deposits as a thin-film on the substrate facing the target. PVD is a vacuum deposition method in which the thin-film goes from a condensed phase to a vapor phase and then back to a condensed phase. CVD is a vacuum deposition method in which the substrate is exposed to volatile precursors, which react and/or decompose on the substrate surface to produce the desired deposition of the thin-film. The main requirement to enable the process are the right selection of precursors which provide the desired wettability and the ability to deposit a stable thin film.

In some embodiments, the thin-film includes perfluorodecyltrichlorosilane (FDTS) or any other hydrophobic material. The surface of the substrate is completely covered by thin-film. The thinness of the thin-film is a few nanometers.

The thin-film including hydrophobic FDTS using MVD creates surface wetting properties, alters many materials which are used in the manufacturing micromodels, e.g., silicon, glass, polydimethylsiloxane, and polymer-based photoresists.

In case of a hydrophilic substrate, the deposited thin-film should be hydrophobic. On the other hand, if the substrate is hydrophobic, the thin-film should be hydrophilic. In this way, a mixed wet-surface is manufactured.

In step 114, remaining photoresist covered with the thin-film is removed. The remaining photoresist is removed using a solvent. In some embodiments, the solvent is N-methyl pyrrolidone (NMP). The remaining photoresist is removed to restore the original substrate surface. A mixed wettability surface is created where the regions covered with FDTS are hydrophobic while the regions without deposited FDTS are hydrophilic.

After removing the remaining photoresist, the surface of the substrate is patterned both with a region covered with the hydrophobic thin-film and an uncovered region where the hydrophilic substrate is uncovered. In other words, the surface of the substrate is mixed of a hydrophobic and a hydrophilic region. Since the hydrophobic and a hydrophilic region have a different wettability, the surface of the substrate is a mixed wettability surface. The substrate with the mixed wettability surface is used as the micromodel, e.g., to represent a reservoir rock.

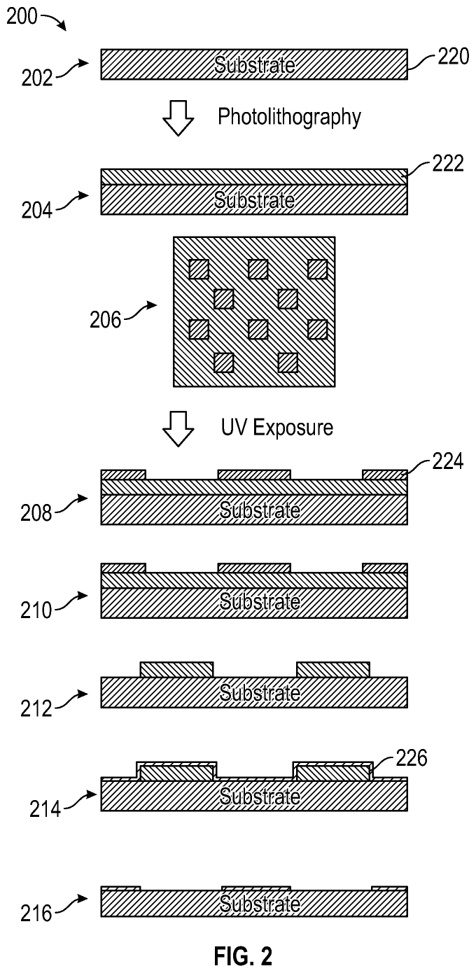

FIG. 2 shows a schematic diagram (200) depicting a substrate 220 undergoing the first method for manufacturing a mixed wettability surface.

In a first step 202, the surface of a silicon-based hydrophilic substrate 220, such as a wafer, is dehydrated and baked at a temperature of 150° C. (300° F.) to remove any moisture on the surface of the substrate 220. This step is optional. Subsequently, an adhesion promoter is applied to the surface to facilitate adhesion of the photoresist 222 (see step 204) to the surface of the substrate 220. Before applying the adhesion promoter, the surface of the substrate 220 may be activated to improve the adhesion of the surface of the substrate 220.

The surface of the substrate 220 may be activated by plasma cleaning that removes impurities and contaminants from the surface of the substrate 220 by an energetic plasma created from a gas. The gas may be argon, oxygen, or a mixture of air, hydrogen, and nitrogen. The plasma is created by using a high frequency voltage to ionize the low pressure gas. In some embodiments, oxygen plasma may be used for surface activation.

In the next step 204, the treated top surface of the substrate 220 is coated with photoresist 222.

In step 206, a top of the photoresist 222 is covered with a photomask 224, wherein the photomask 224 includes a pattern transparent to UV light. The photomask 224 is called selective wettability control mask and is aligned on top of the photoresist 222. In some embodiments, the pattern of the photomask 224 includes holes that allow UV light to shine through the photomask 224.

In step 208, the covered top of the photoresist 222 is exposed to UV light that changes a chemical property of a region of the photoresist 222 corresponding to the pattern of the photomask 224.

In step 210, the coated substrate 220 is baked at a high temperature (e.g., 110° C.) to solidify the photoresist 222. After the baking, the photomask 224 is removed.

In step 212, a region of the photoresist 222 is removed based on the chemical property of the region, wherein the removed region corresponds to the pattern of the photomask 224. A solvent, called photoresist 222 developer, is applied to the surface of the substrate 220 to remove the region of the photoresist 222 that also corresponds to the pattern of the region exposed to UV light.

In step 214, a hydrophobic thin-film 226 is deposited on top of the substrate 220.

In step 216, remaining photoresist covered with the thin-film 226 is removed, such that the surface of the substrate 220 is patterned with a region covered with the hydrophobic thin-film 226, and an uncovered region of the hydrophilic substrate 220, creating a mixed wettability surface on the substrate 220 that represents the micromodel.

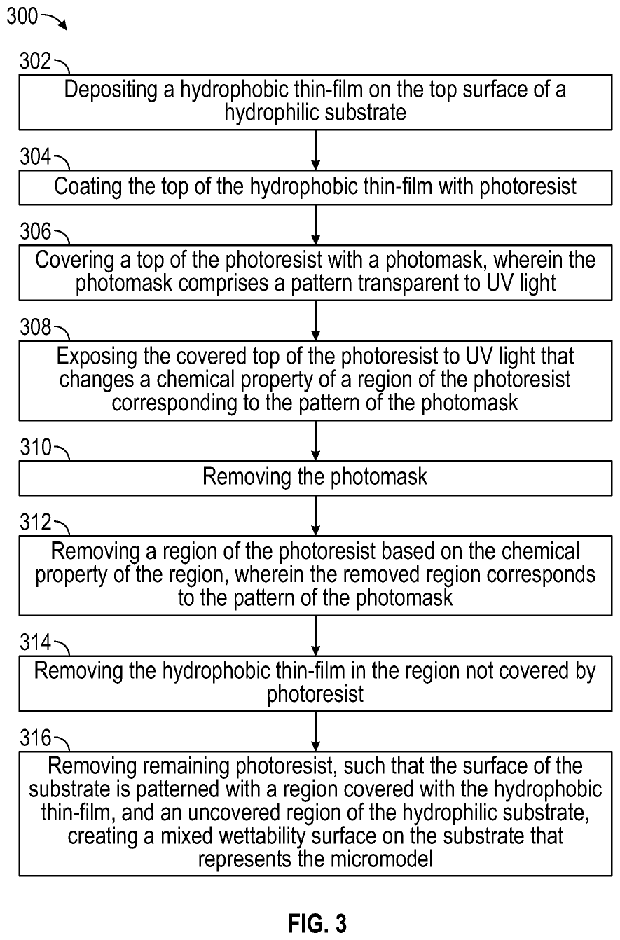

FIG. 3 shows a flowchart (300) of the method steps for manufacturing a mixed wettability surface, according to the second method. The second method includes the following steps.

In step 302, a hydrophobic thin-film is deposited on the top surface of a hydrophilic substrate.

In step 304, the top of the hydrophobic thin-film is coated with photoresist.

In step 306, a top of the photoresist is covered with a photomask, wherein the photomask includes a pattern transparent to UV light.

In step 308, the covered top of the photoresist is exposed to UV light that changes a chemical property of a region of the photoresist corresponding to the pattern of the photomask.

In step 310, the photomask is removed.

In step 312, a region of the photoresist is removed based on the chemical property of the region, wherein the removed region corresponds to the pattern of the photomask.

In step 314, the hydrophobic thin-film in the region not covered by photoresist is removed.

In step 316, remaining photoresist is removed, such that the surface of the substrate is patterned with a region covered with the hydrophobic thin-film, and an uncovered region of the hydrophilic substrate, creating a mixed wettability surface on the substrate that represents the micromodel.

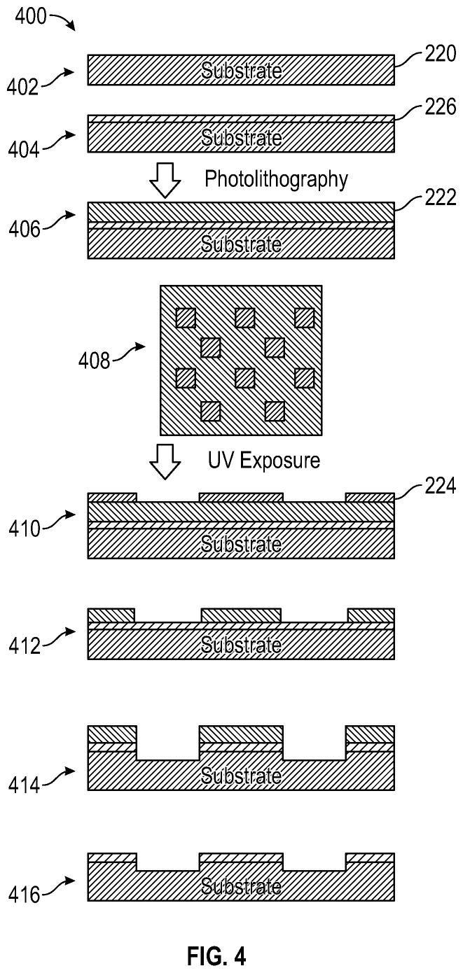

FIG. 4 shows a substrate 220 undergoing the second method for manufacturing a mixed wettability surface.

The first step 402 is the initial surface cleaning & treatment step. This step is optional and may be applied to the surface of any silicon-based substrate 220. In some embodiments, piranha solution or a solution comprising hydrofluoric acid is applied to the surface of the substrate 220.

In step 404, a hydrophobic thin-film 226 is deposited on the top surface of a hydrophilic substrate 220.

In step 406, the top of the hydrophobic thin-film 226 is coated with photoresist 222. Then, the substrate 220 is soft baked on a hot plate to remove any volatile solvents in the photoresist 222.

In step 408, a top of the photoresist 222 is covered with a photomask 224, wherein the photomask 224 includes a pattern transparent to UV light. The photomask 224, also called selective wettability control mask, is aligned on top of the photoresist 222.

In step 410, exposing the covered top of the photoresist 222 to UV light that changes a chemical property of a region of the photoresist 222 corresponding to the pattern of the photomask 224. Then, the photomask 224 is removed.

In step 412, a region of the photoresist 222 is removed based on the chemical property of the region, wherein the removed region corresponds to the pattern of the photomask 224. Step 412 is called the development step.

In step 414, the hydrophobic thin-film 226 in the region not covered by photoresist 222 is removed. In some embodiments, the thin-film 226 regions uncovered with photoresist 222 are removed from the substrate 220 by etching. Therefore, step 414 is called the etching step. For the etching, a strong acid or mordant is used to cut into the uncovered regions of the thin-film 226.

In step 416, remaining photoresist 222 is removed, such that the surface of the substrate 220 is patterned with a region covered with the hydrophobic thin-film 226, and an uncovered region of the hydrophilic substrate 220, creating a mixed wettability surface on the substrate 220 that represents the micromodel. The remaining photoresist 222 is removed using a solvent. In some embodiments, the photoresist 222 includes NMP. A mixed wettability surface is created where the regions covered with FDTS are hydrophobic while the regions without FDTS are hydrophilic.

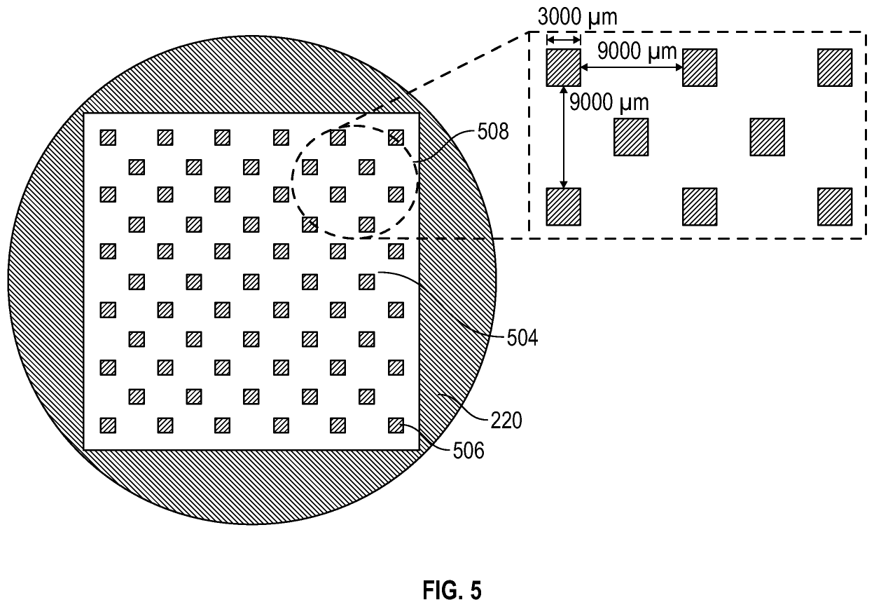

FIG. 5 shows a schematic view of a substrate 220 with a mixed wettability surface manufactured by a wettability control mask according to the first method. The substrate includes hydrophilic regions 504 and hydrophobic regions 506. The hydrophobic regions 506 are patterned with squares. The squares are coated with FDTS, according to step 214 of the first method. The dimensions of the squares are shown in a magnification 508 of the surface of the substrate 220.

As an example for illustration purpose only, each square has a lateral length of 3000 μm. The distance of a square to the neighboring square is 9000 μm. The hydrophobicity may be tested as described in step 212 of the first method.

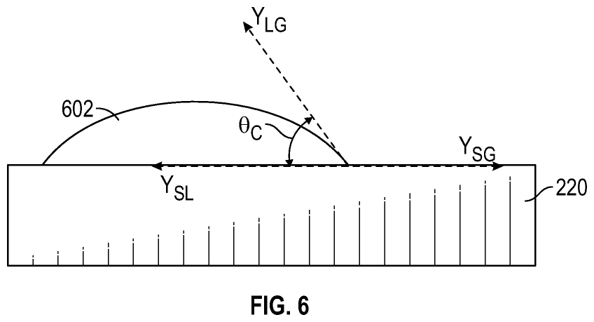

FIG. 6 shows a water droplet 602 on the surface of the substrate 220. The contact angle θ_{C} of a water droplet is the angle between the liquid-vapor interface of the water droplet and the (solid) surface of the substrate 220. The contact angle θ_{C} describes the wettability of surface of the substrate by the water droplet by Young's equation:

γ_{SG}=γ_{SL}+γ_{LG}^{COS}(θ_{C})

where γ^{SG} is the surface free energy of the substrate, γ_{SL}, is the interfacial tension between the water droplet and the substrate, and γ_{LG} is the surface tension of the water droplet.

The equilibrium contact angle θ G reflects the relative strength of the molecular interaction between the water droplet and the substrate.

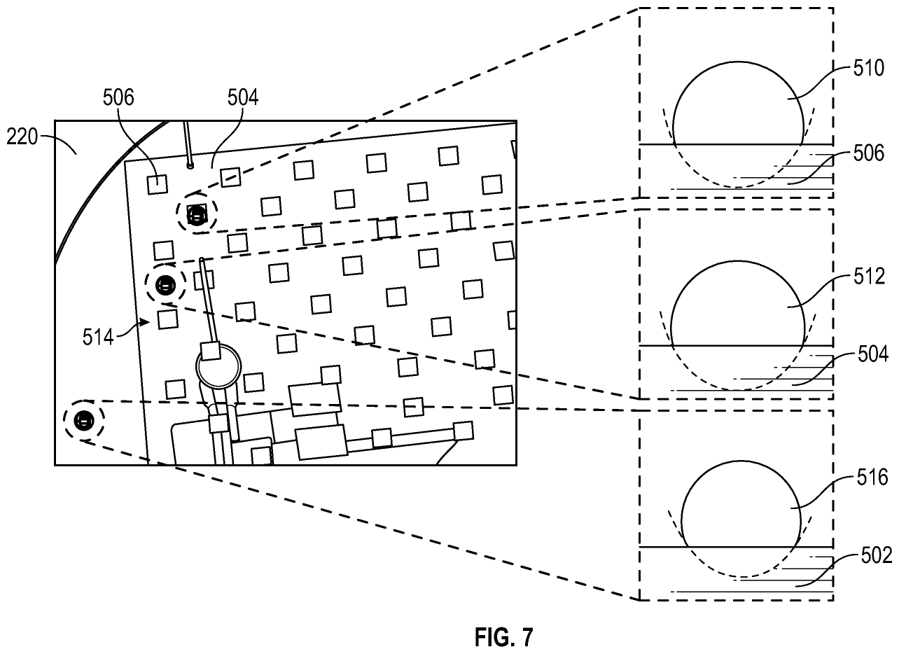

FIG. 7 shows the substrate 220 of FIG. 5 with deionized water droplets on the surface of the substrate. The water droplets 510 and 512 are disposed across a region fully coated with hydrophobic material FDTS on locations 506 and 504, respectively. The water droplet 516 is disposed directly on a non-treated surface (502) of the substrate.

The contact angle of the water droplet 510 is 117°. The contact angle of the water droplet 512 is 110°. The contact angle of the water droplet 516 is 119.5°. This illustrates the non-selectivity in surface fully coated with hydrophobic material such that all contact angles show high values in different locations.

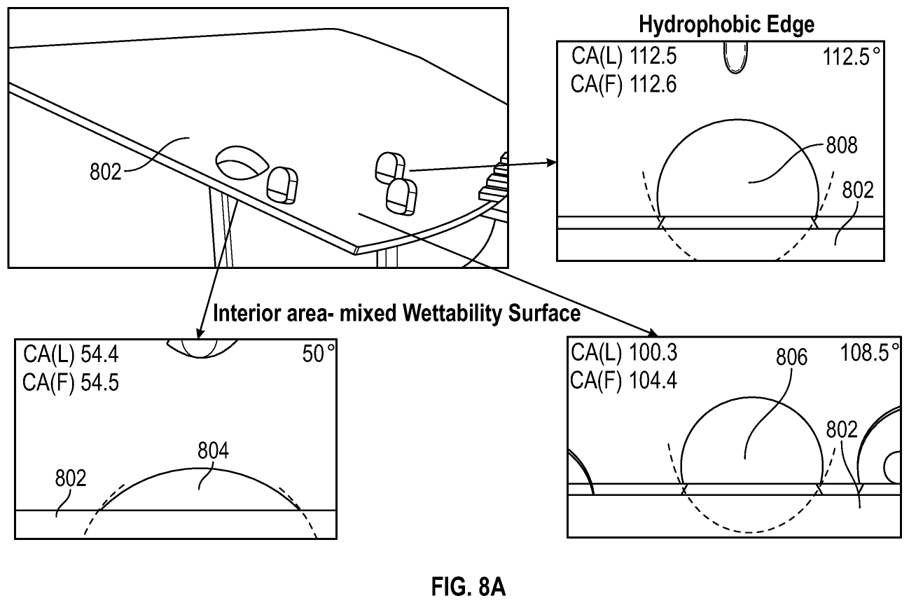

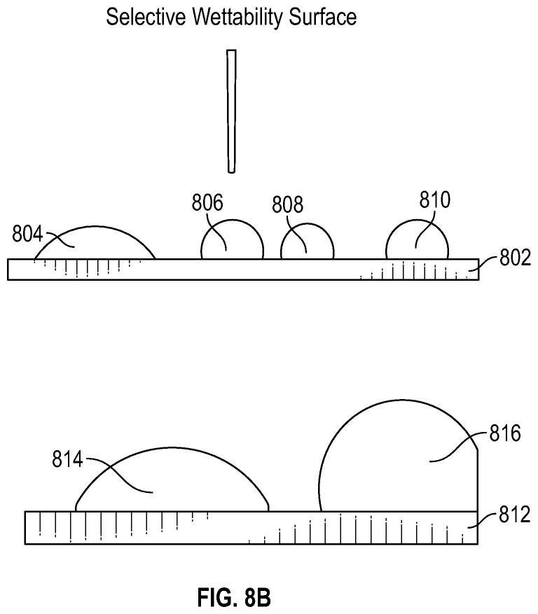

FIG. 8A shows a silicon-based substrate 802 with a selective mixed wettability surface, manufactured by the first method. The selective mixed wettability surface is manufactured after removing the photoresist in step 214 of the first method. A solvent including NMP was used to lift off the remaining photoresist and FDTS from the substrate to restore the original surface of the substrate.

Three water droplets 804, 806, 808, disposed on the surface 802 are magnified in FIG. 8A. The first water droplet is disposed on a region not covered by FDTS and has, therefore, a contact angle of 50°. The second and third water droplets are disposed on a region covered with FDTS and have, therefore, a contact angle of 108.5° and 112.5°, respectively.

The contact angles of the three water droplets verified the selective mixed wettability of the surface as manufactured according to the first method. The regions covered with FDTS are hydrophobic while the regions not covered by FDTS are hydrophilic, establishing a large contrast in water and air contact angle.

FIG. 8B shows a first surface 802 with four water droplets 804, 806, 808, 810 and a second surface 812 with two water droplets 814, 816. On the first surface 802, the first water droplet 804 has a small contact angle, wherein the second, third, and fourth water droplets 806, 808, 810 have a large contact angle. On the second surface 812, the first water droplet 814 has a small contact angle, wherein the second water droplet 816 has a large contact angle.

Although only a few example embodiments have been described in detail above, those skilled in the art will readily appreciate that many modifications are possible in the example embodiments without materially departing from this invention. Accordingly, all such modifications are intended to be included within the scope of this disclosure as defined in the following claims. In the claims, means-plus-function clauses are intended to cover the structures described herein as performing the recited function and not only structural equivalents, but also equivalent structures. Thus, although a nail and a screw may not be structural equivalents in that a nail employs a cylindrical surface to secure wooden parts together, whereas a screw employs a helical surface, in the environment of fastening wooden parts, a nail and a screw may be equivalent structures. It is the express intention of the applicant not to invoke 35 U.S.C. § 112(f) for any limitations of any of the claims herein, except for those in which the claim expressly uses the words ‘means for’ together with an associated function.

What is claimed is:

1. A method for manufacturing a micromodel with a mixed wettability surface representing a hydrocarbon reservoir, comprising the steps:
coating a top surface of a hydrophilic substrate with photoresist,
covering a top of the photoresist with a photomask, wherein the photomask comprises a pattern transparent to UV light,
exposing the covered top of the photoresist to UV light that changes a chemical property of a region of the photoresist corresponding to the pattern of the photomask,
removing the photomask,
removing the region of the photoresist corresponding to the pattern of the photomask based on the chemical property of the region,
depositing a hydrophobic thin-film on top of the hydrophilic substrate, and
removing a remaining photoresist covered with the thin-film, such that the surface of the hydrophilic substrate is patterned with both a region covered with the hydrophobic thin-film and an uncovered region of the hydrophilic substrate, creating a mixed wettability surface on the hydrophilic substrate that represents the micromodel.

2. The method according to claim 1, wherein the region of the photoresist is removed by applying photoresist developer to the photoresist.

3. The method according to claim 2, wherein the photoresist is positive, and the region of the photoresist exposed to UV light is degraded and becomes soluble to the photoresist developer, while a region of the photoresist covered by the photomask from the UV light remains undegraded and insoluble to the photoresist developer.

4. The method according to claim 2, wherein the photoresist is negative, and a region of the photoresist exposed to UV light is strengthened by the UV light and becomes insoluble to a photoresist developer, while a region unexposed to the UV light remains weak and insoluble to the photoresist developer.

5. The method according to claim 1, wherein the photoresist is applied by spin coating.

6. The method according to claim 1, wherein the thin-film is deposited by atomic layer deposition (ALD), molecular layer deposition (MVD), pulsed laser deposition (PLD), physical vapor deposition (PVD), chemical vapor deposition (CVD), sputtering, or evaporation.

7. The method according to claim 1, wherein the thin-film comprises perfluorodecyltrichlorosilane (FDTS).

8. The method according to claim 1, wherein the remaining photoresist is removed by N-methyl pyrrolidone (NMP).

9. The method according to claim 1, wherein the hydrophilic substrate is baked at a temperature of 150° C. (300° F.) before coating the surface of the substrate with photoresist.

10. The method according to claim 9, wherein an adhesion promoter is applied to the surface of the substrate after baking the substrate.

11. The method according to claim 1, wherein the surface of the substrate is activated by plasma cleaning, before coating the surface of the substrate with photoresist.

12. The method according to claim 11, wherein the plasma cleaning is performed by oxygen plasma.

13. The method according to claim 1, wherein the coated substrate is baked at a temperature of 110° C. after exposing the covered top of the photoresist to UV light.

14. A method for manufacturing a micromodel with a mixed wettability surface representing a hydrocarbon reservoir, comprising the steps:
coating a top surface of a hydrophobic substrate with photoresist,
covering a top of the photoresist with a photomask, wherein the photomask comprises a pattern transparent to UV light,
exposing the covered top of the photoresist to UV light that changes a chemical property of a region of the photoresist corresponding to the pattern of the photomask,
removing the photomask,
removing the region of the photoresist based on the chemical property of the region, wherein the removed region corresponds to the pattern of the photomask,
depositing a hydrophilic thin-film on top of the substrate, and
removing a remaining photoresist covered with the hydrophilic thin-film, such that the surface of the hydrophobic substrate is patterned with both a region covered with the hydrophilic thin-film and an uncovered region of the hydrophobic substrate, creating a mixed wettability surface on the hydrophobic substrate that represents the micromodel.

15. A method for manufacturing a micromodel with a mixed wettability surface representing a hydrocarbon reservoir, comprising the steps:
depositing a hydrophobic thin-film on a top surface of a hydrophilic substrate,
coating a top of the hydrophobic thin-film with photoresist,
covering a top of the photoresist with a photomask, wherein the photomask comprises a pattern transparent to UV light,
exposing the covered top of the photoresist to UV light that changes a chemical property of a region of the photoresist corresponding to the pattern of the photomask,
removing the photomask,
removing a region of the photoresist based on the chemical property of the region, wherein the removed region corresponds to the pattern of the photomask,
removing the hydrophobic thin-film in the region not covered by photoresist, and
removing remaining photoresist, such that the surface of the substrate is patterned with both the region covered with the hydrophobic thin-film and an uncovered region of the hydrophilic substrate, creating a mixed wettability surface on the substrate that represents the micromodel.

16. A method for manufacturing a micromodel with a mixed wettability surface representing a hydrocarbon reservoir, comprising the steps:
depositing a hydrophilic thin-film on a top surface of a hydrophobic substrate,
coating a top of the thin-film with photoresist,
covering a top of the photoresist with a photomask, wherein the photomask comprises a pattern transparent to UV light,
exposing the covered top of the photoresist to UV light that changes a chemical property of a region of the photoresist corresponding to the pattern of the photomask,
removing the photomask,
removing a region of the photoresist based on the chemical property of the region, wherein the removed region corresponds to the pattern of the photomask,
removing the thin-film in the region not covered by photoresist, and
removing remaining photoresist, such that the surface of the substrate is patterned with both a region covered with the hydrophilic thin-film and an uncovered region of the hydrophobic substrate, creating a mixed wettability surface on the substrate that represents the micromodel.

17. The method according to claim 16, wherein the thin-film is removed by etching the surface of the substrate.
